(19) United States
(12) Patent Application Publication
(10) Pub. No.: US 2024/0387506 A1
(43) Pub. Date: Nov. 21, 2024

(54) UNIDIRECTIONAL TRANSIENT VOLTAGE SUPPRESSION DIODE AND MANUFACTURING PROCESS

(71) Applicant: WILL SEMICONDUCTOR (SHANGHAI) CO. LTD., Shanghai (CN)

(72) Inventors: Zhongrui WU, Shanghai (CN); Dong ZHANG, Shanghai (CN); Yonghai HU, Shanghai (CN); Ruiqian XI, Shanghai (CN); Pan ZHAO, Shanghai (CN); Yifeng LU, Shanghai (CN)

(73) Assignee: WILL SEMICONDUCTOR (SHANGHAI) CO. LTD., Shanghai (CN)

(21) Appl. No.: 18/570,270

(22) PCT Filed: Sep. 30, 2021
(86) PCT No.: PCT/CN2021/122377

§ 371 Date: Dec. 14, 2023

(30) Foreign Application Priority Data
Sep. 29, 2021 (CN) 202111154291.6

(51) Int. Cl. H01L 27/02; H01L 29/66; H01L 29/861

(52) U.S. Cl. CPC H01L 27/0248; H01L 29/66106; H01L 29/861

(57) ABSTRACT

A unidirectional transient voltage suppression diode and a process, including a substrate of a first conductivity type and a first implantation region and a second implantation region of a second conductivity type, where the first implantation region is disposed on a front side of the substrate, and the second implantation region is disposed on a back side of the substrate. Depth of a pn junction formed between the second implantation region and the substrate is less than that between the first implantation region and the substrate. First metal is led out of the first implantation region as a first electrode, an insulation layer is disposed between a barrier layer and a first metal layer, and second metal is led out of the second implantation region on the back side and the substrate respectively as a second electrode.

### TECHNICAL FIELD

Embodiments of this application relate to the field of semiconductor technologies, and specifically, to a unidirectional transient voltage suppression diode and a manufacturing process thereof.

### BACKGROUND

Surge is the instantaneous overvoltage on an electric device that exceeds normal operating voltage. The instantaneous energy produced by a surge is huge enough to damage circuits. A TVS (transient voltage suppression diode) is a commonly used surge protector that can effectively protect circuits.

As the application environment becomes increasingly complex, circuits require a higher surge protection capability. Increasing the area of protection devices can improve the surge protection capability, but this also increases costs. With the growing integration level, the area of surge protectors becomes smaller. Therefore, it is crucial to improve the surge protection capability without increasing the area.

In addition, TVS reliability is vulnerable to electric charges. An unstable breakdown voltage will result in many problems in actual application. Therefore, it is also important to improve the TVS reliability and guarantee breakdown voltage stability, so as to enable devices to operate properly for a long time.

### SUMMARY

Embodiments of this application are intended to provide an ultra-low-capacitance ESD protection device and a manufacturing method thereof. The embodiments of this application can improve the surge protection capability and reliability of unidirectional TVSs.

According to a first aspect, an embodiment of this application provides a unidirectional transient voltage suppression diode including a substrate of a first conductivity type, and a first implantation region and a second implantation region of a second conductivity type.

The first implantation region is disposed on a front side of the substrate, the second implantation region is disposed on a back side of the substrate, and depth of a pn junction formed between the second implantation region and the substrate is less than depth of a pn junction formed between the first implantation region and the substrate.

A barrier layer and an insulation layer are arranged in sequence on a front surface of the substrate from the bottom up: first metal is led out of the first implantation region as a first electrode, the insulation layer is disposed between the barrier layer and a first metal layer, and second metal is led out of the second implantation region on the back side and the substrate respectively as a second electrode, so that the second implantation region on the back side of the substrate is short-circuited with the substrate; and the first conductivity type is different from the second conductivity type.

Different from the prior art, in the embodiment of the first aspect, the insulation layer is disposed between the barrier layer and the first metal layer, and the depth of the pn junction formed between the second implantation region and the substrate is less than the depth of the pn junction formed between the first implantation region and the substrate. The insulation layer is used to shield electric charges, ensuring that the breakdown voltage of the diode is not affected. In addition, the depth of the junction with the second implantation region on the back side of the substrate is shallow, improving the negative surge protection capability.

According to a second aspect, an embodiment of this application provides another unidirectional transient voltage suppression diode including a substrate of a first conductivity type, a first implantation region and a second implantation region of a second conductivity type, and a trough.

The first implantation region is disposed on a front side of the substrate, the second implantation region is disposed on a back side of the substrate, and depth of a pn junction formed between the second implantation region and the substrate is less than depth of a pn junction formed between the first implantation region and the substrate.

The trough covers the first implantation region, a separation layer is implanted on a wall of the trough, and depth of the trough is greater than the depth of the pn junction formed between the first implantation region and the substrate. First metal is led out of the first implantation region as a first electrode, and second metal is led out of the second implantation region on the back side and the substrate respectively as a second electrode, so that the second implantation region on the back side of the substrate is short-circuited with the substrate. The first conductivity type is different from the second conductivity type.

Different from the prior art, in the embodiment of the second aspect, the trough is disposed around the first implantation region, the separation layer is implanted on the wall of the trough, the depth of the trough is greater than the depth of the pn junction formed between the first implantation region and the substrate, and the depth of the pn junction formed between the second implantation region and the substrate is less than depth of the pn junction formed between the first implantation region and the substrate. The trough is used for shielding electric charges, ensuring that the breakdown voltage of the diode is not affected. In addition, the depth of the junction with the second implantation region on the back side of the substrate is shallow, improving the negative surge protection capability.

According to a third aspect, an embodiment of this application provides a manufacturing process of unidirectional transient voltage suppression diode, where the manufacturing process is used for manufacturing the diode according to the first aspect. The manufacturing process includes:
forming a barrier layer on a substrate of a first conductivity type:
sequentially forming a first implantation region on a front side of the substrate and a second implantation region on a back side, where the first implantation region and the second implantation region are of the first conductivity type, depth of a pn junction formed between the second implantation region and the substrate is less than depth of a pn junction formed between the first implantation region and the substrate, and the first conductivity type is different from a second conductivity type;
forming a second implantation region on a back side of the substrate, where the first implantation region and the second implantation region are of a second conductivity type, the depth of the pn junction formed between the second implantation region and the substrate is less than the depth of the pn junction formed between the first implantation region and the substrate, and the first conductivity type is different from the second conductivity type;
forming an insulation layer on top of the barrier layer on the front side of the substrate; and
leading first metal out of the first implantation region as a first electrode, where the insulation layer is disposed between the barrier layer and a first metal layer, and leading second metal out of the second implantation region and the substrate respectively as a second electrode, so that the second implantation region on the back side of the substrate is short-circuited with the substrate.

Compared with the prior art, beneficial effects of the embodiment of the third aspect are the same as beneficial effects of the unidirectional transient voltage suppression diode provided in the embodiment of the first aspect.

According to a fourth aspect, an embodiment of this application provides a manufacturing process of unidirectional transient voltage suppression diode, where the manufacturing process is used for manufacturing the diode according to the second aspect. The manufacturing process includes:
forming a first implantation region on a front side of a substrate;
forming a trough on the front side of the substrate and forming a separation layer in the trough, where the trough covers the first implantation region, and depth of the trough is greater than depth of a pn junction formed between the first implantation region and the substrate;
forming a second implantation region on a back side of the substrate, where the first implantation region and the second implantation region are of a first conductivity type, depth of a pn junction formed between the second implantation region and the substrate is less than the depth of the pn junction formed between the first implantation region and the substrate, and the first conductivity type is different from a second conductivity type; and
leading first metal out of the first implantation region as a first electrode and leading second metal out of the second implantation region and the substrate respectively as a second electrode, so that the second implantation region on the back side of the substrate is short-circuited with the substrate.

Compared with the prior art, beneficial effects of the unidirectional transient voltage suppression diode provided in the fourth aspect are the same as those of the technical solution provided in the second aspect. Details are not described herein again.

### BRIEF DESCRIPTION OF DRAWINGS

Non-limiting and non-exhaustive embodiments of the present invention are described by using examples with reference to the following drawings, where

FIG. 1 is a schematic structural diagram of a type of unidirectional transient voltage suppression diodes in the prior art;

FIG. 2 is a schematic structural diagram of an embodiment of this application improved based on the schematic structural diagram of the diode shown in FIG. 1:

FIG. 3 is a schematic structural diagram of an embodiment of this application improved based on the schematic structural diagram of the diode shown in FIG. 1:

FIG. 4 is a schematic structural diagram of an embodiment of this application improved based on the schematic structural diagram of the diode shown in FIG. 1:

FIG. 5 is a schematic structural diagram of an embodiment of this application improved based on the schematic structural diagram of the diode shown in FIG. 1:

FIG. 6 is a schematic structural diagram of an embodiment of this application improved based on the schematic structural diagram of the diode shown in FIG. 1:

FIG. 7 is a schematic structural diagram of an embodiment of this application improved based on the schematic structural diagram of the diode shown in FIG. 2:

FIG. 8 is a schematic structural diagram of an embodiment of this application improved based on the schematic structural diagram of the diode shown in FIG. 2:

FIG. 9 is a schematic structural diagram of an embodiment of this application improved based on the schematic structural diagram of the diode shown in FIG. 2:

FIG. 10 is a schematic structural diagram of an embodiment of this application improved based on the schematic structural diagram of the diode shown in FIG. 2:

FIG. 11 is a flowchart of a manufacturing process according to the embodiments of this application shown in FIG. 2 to FIG. 5; and

FIG. 12 is a flowchart of a manufacturing process according to the embodiments of this application shown in FIG. 7 to FIG. 10.

### DETAILED DESCRIPTION OF EMBODIMENTS

In order to make the foregoing and other features and advantages of the present invention clearer, the present invention will be further described below with reference to the accompanying drawings. It should be understood that the specific embodiments herein are intended to explain to those skilled in the art and therefore are merely exemplary rather than limiting.

To make persons skilled in the art better understand the technical solutions in the present invention, the following clearly and completely describes the technical solutions in the embodiments of the present invention with reference to the accompanying drawings in the embodiments of the present invention. Apparently, the described embodiments are merely some but not all of the embodiments of the present invention. All other embodiments obtained by persons of ordinary skill in the art based on the embodiments of the present invention without creative efforts shall fall within the protection scope of the present invention.

It should be noted that the specification, claims, and the accompanying drawings of the present invention, the terms “first”, “second”, and the like are intended to distinguish similar objects but do not necessarily indicate a specific order or sequence. It should be understood that the data used in this way is interchangeable in appropriate circumstances so that the embodiments of the present invention described herein can be implemented in other orders than the order illustrated or described herein. In addition, the terms “include”, “have”, and any other variants thereof are intended to cover a non-exclusive inclusion. For example, a process, method, system, product, or device that includes a list of steps or units is not necessarily limited to those steps or units that are expressly listed, but may include other steps or units that are not expressly listed or are inherent to such process, method, product, or device.

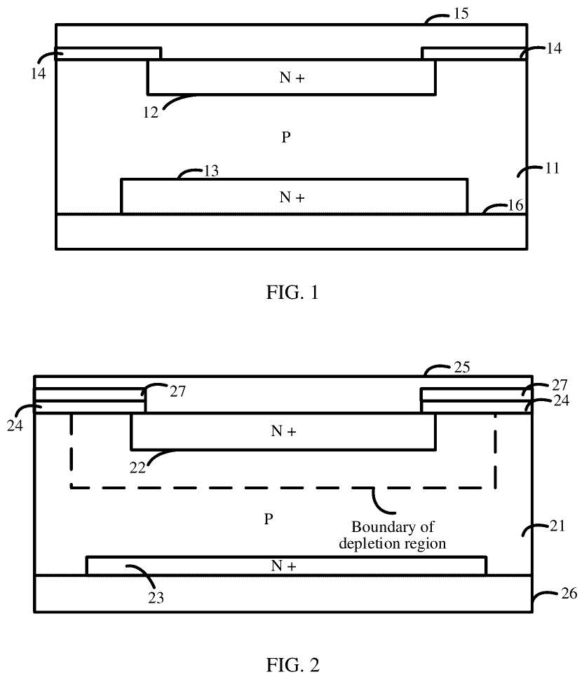

As shown in FIG. 1, FIG. 1 is a schematic structural diagram of a unidirectional transient voltage suppression diode in the prior art. The specific structure shown in FIG. 1 is as follows.

Implantation regions 12 and 13 with the same junction depth are sequentially disposed on the front side and back side of a substrate 11 respectively. The implantation region 13 on the back side is connected to the substrate 11 through metal 16, so that the implantation region 13 on the back side of the substrate 11 is short-circuited with the substrate 11. The implantation region 12 on the front side of the substrate 11 is connected to metal 15, and the implantation region 12 on the front side of the substrate 11 is separated from the substrate 11 by a barrier layer 14, where the barrier layer 14 is made of silicon dioxide. The implantation region 12 on the front side of the substrate 11 and the implantation region 13 on the back side of the substrate 11 are of the same conductivity type but different from the conductivity type of the substrate 11, where the substrate 11 may be P-type and the implantation region 12 and the implantation region 13 are both N-type. Depth of a pn junction between the implantation region 12 on the front side of the substrate 11 and the substrate 11 is the same as depth of a pn junction between the implantation region 13 on the back side and the substrate 11. In the prior art, the breakdown voltage of the device is vulnerable to electric charges on the barrier layer 14, and protection against negative surges is provided only by a forward-biased pn junction formed between the substrate 11 and the implantation region 12 on the front side of the substrate 11. In this case, the surge protection capability is weak. In the prior art, only one barrier layer 14 is present between the implantation region 12 on the front side and the metal layer 15. During chip manufacturing, electric charges are easily generated at the interface of the barrier layer 14 and form an electric field. This will cause changes in the depletion region of a pn junction, leading to a drift in breakdown voltage. The negative surge refers to a surge where the current flows from the back side to the front side of the substrate 11. There are two paths from the back side to the front side of the substrate 11: path 1 being from the substrate 11 to the implantation region 12 on the front side and path 2 being from the implantation region 13 on the back side to the substrate 11 to the implantation region 12 on the front side. In the prior art, because the pn junction formed between the implantation region 13 on the back side and the substrate 11 is a high voltage-resistant reverse-biased junction, path 2 is unavailable, and current can only be discharged along path 1. As a result, the current flowing area is small, a large amount of heat is generated, and the surge protection capability is weak.

In order to solve the problem in the structure shown in FIG. 1 in the prior art, the applicants have proposed the following specific embodiments through research.

### Embodiment 1

As shown in FIG. 2, an embodiment of this application provides a unidirectional transient voltage suppression diode including a substrate 21 of a first conductivity type, and a first implantation region 22 and a second implantation region 23 of a second conductivity type.

The first implantation region 22 is disposed on a front side of the substrate 21, the second implantation region 23 is disposed on a back side of the substrate 21, and depth of a pn junction formed between the second implantation region 23 and the substrate 21 is less than depth of a pn junction formed between the first implantation region 22 and the substrate 21. A barrier layer 24 and an insulation layer 27 are arranged in sequence on a front surface of the substrate 21 from the bottom up. First metal 25 is led out of the first implantation region 22 as a first electrode, the insulation layer 27 is disposed between the barrier layer 24 and a first metal layer 25, and second metal 26 is led out of the second implantation region 23 on the back side and the substrate 21 respectively as a second electrode, so that the second implantation region 23 on the back side of the substrate 21 is short-circuited with the substrate 21. The first conductivity type is different from the second conductivity type. In the embodiment of this application, both the first implantation region 22 and the second implantation region 23 are heavily doped.

In the embodiment of this application, the first conductivity type is P-type and the second conductivity type is N-type, forming an NPN structure. In another embodiment, the first conductivity type may be N-type and the second conductivity type may be P-type, forming a PNP structure. The barrier layer 24 is made of silicon dioxide, playing a role in isolation and blocking. The insulation layer 27 is phosphorus-doped silica and serves to prevent short circuit. The breakdown voltage drift of a diode device is affected by electric charges. Phosphorus-doped silica contains many unsaturated dangling bonds which can implement electric field shielding.

In the embodiment of this application, width of the second implantation region 23 is greater than that of the first implantation region 22, mainly in consideration of allocation of positive and negative surge protection capabilities. A wider second implantation region 23 on the back side corresponds to a higher positive surge protection capability but a lower negative surge protection capability. The second implantation region 23 on the back side being wider than the first implantation region 22 on the front side allows the positive and negative surge protection capabilities to be effectively allocated.

### Embodiment 2

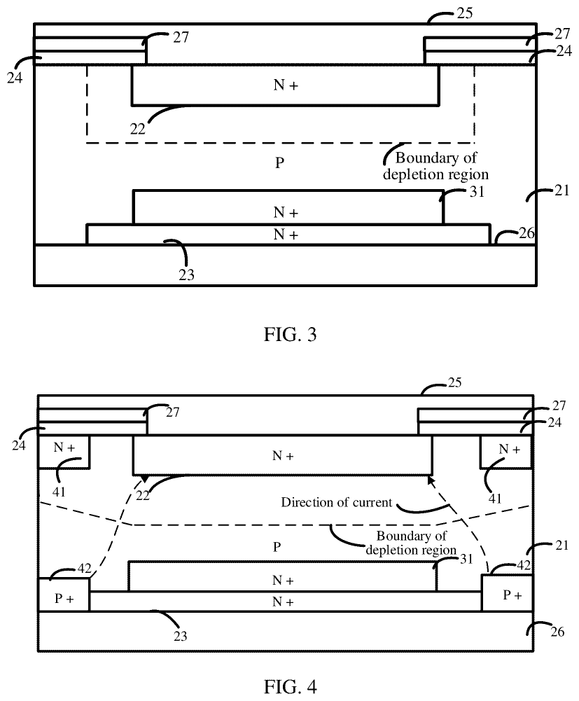

On a basis of Embodiment 1, as shown in FIG. 3, the diode in the embodiment of this application further includes a third implantation region 31 of a second conductivity type. The reason for setting the second implantation region 23 to be wider than the third implantation region 31 is that the second implantation region 23 on the back side is an electron emission region. A quantity of electrons that can be emitted is related to the area. A larger area means more electrons emitted and stronger current-flowing capability. In the embodiment of this application, depth of a pn junction formed between the third implantation region 31 and the substrate 21 is greater than the depth of the pn junction formed between the first implantation region 22 and the substrate 21. The second implantation region 23 is heavily doped. In the embodiment of this application, the first conductivity type is P-type, and the second conductivity type is N-type. If the substrate 21 is P-type, the third implantation region 31 is N-type; and if the substrate 21 is N-type, the third implantation region 31 is P-type. In another embodiment, the first conductivity type may be N-type, and the second conductivity type is P-type. In the embodiment of this application, the third implantation region 31 shortens a base region that includes the first implantation region 22 on the front side, the substrate 21, and the second implantation region 23 on the back side, increasing the current magnification factor and thereby increasing the current-carrying capability.

In the embodiment of this application, width of the second implantation region 23 is greater than that of the first implantation region 22, mainly in consideration of allocation of positive and negative surge protection capabilities. A wider second implantation region 23 on the back side corresponds to a higher positive surge protection capability but a lower negative surge protection capability. The second implantation region 23 on the back side being wider than the first implantation region 22 on the front side allows the positive and negative surge protection capabilities to be effectively allocated.

### Embodiment 3

On a basis of Embodiment 2, as shown in FIG. 4, the unidirectional transient voltage suppression diode in the embodiment of this application further includes a fourth implantation region 42 of the first conductivity type and/or a fifth implantation region 41 of the second conductivity type. The fifth implantation region 41 covers the first implantation region 22 and is spaced apart from the first implantation region 22 by a predetermined distance. Such separation by a predetermined distance allows the boundary of the depletion region on the surface to extend smoothly. The fourth implantation region 42 covers the second implantation region 23 and is in contact with the second implantation region 23. A pn junction can be formed between the fourth implantation region 42 and the second implantation region 23 on the back side of the substrate only when the fourth implantation region 42 is in contact with the second implantation region 23: otherwise, a pn junction is formed between the substrate 21 and the second implantation region 23 on the back side of the substrate is formed.

In the embodiment of this application, the unidirectional transient voltage suppression diode may alternatively include only the fourth implantation region 42 of the first conductivity type or the fifth implantation region 41 of the second conductivity type.

In this embodiment, if the substrate 21 is P-type, the fourth implantation region 42 is P-type and the fifth implantation region 41 is N-type. The P-type fourth implantation region 42 and the N-type fifth implantation region 41 are heavily doped.

In this embodiment, due to existence of the fifth implantation region 41, an edge of the depletion region of the pn junction formed between the first implantation region 22 on the front side of the substrate and the substrate 21 extends more smoothly compared with such pn junction described in Embodiment 1 and Embodiment 2. In this case, breakdown is more likely to occur inside other than on the surface, and electric charges are present on the surface. If breakdown occurs on the surface, the breakdown voltage is affected.

The fourth implantation region 42 is heavily doped. A P region and an N region of a pn junction formed between the fourth implantation region 42 and the fifth implantation region 41 are heavily doped, and therefore are greatly vulnerable to Zener breakdown that features a low breakdown voltage. When a negative surge occurs, a path, which leads from the fourth implantation region 42 on the back side of the substrate to the substrate 21 and to the first implantation region 22 on the front side of the substrate, is more likely to be established for current to flow through.

### Embodiment 4

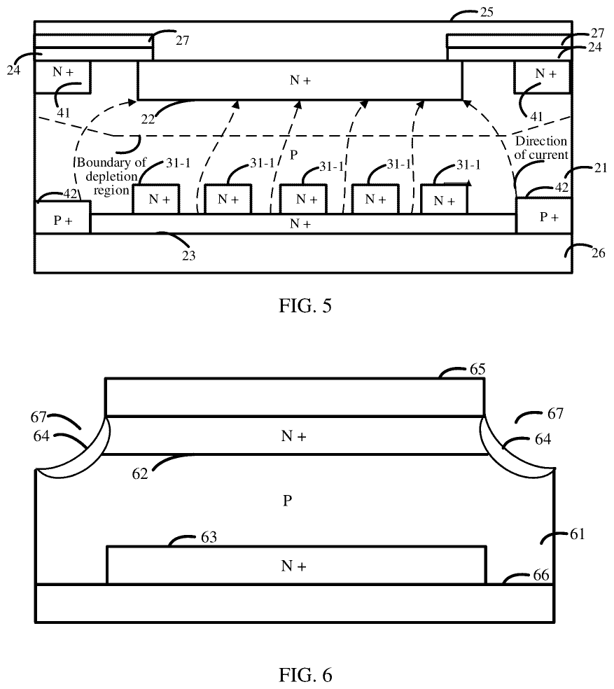

Embodiment 4 is based on Embodiment 3. As shown in FIG. 5, the third implantation regions are a plurality of segmented implantation regions 31-1 that are evenly spaced apart.

It should be noted that the third implantation regions 31 in Embodiment 2 may also be a plurality of segmented implantation regions that are spaced apart. In addition, due to existence of the fifth implantation region 41, the edge of the depletion region of the pn junction formed between the first implantation region 22 on the front side of the substrate and the substrate 21 extends more smoothly compared with such pn junction described in Embodiment 2 and Embodiment 3.

In the embodiment of this application, when a negative surge occurs, the path from the fourth implantation region 42 on the back side of the substrate to the first implantation region 22 on the front side of the substrate 21 can be conducted more easily, allowing current to flow on. The conduction area is larger, allowing currents to be more evenly distributed, instead of gathering at both ends.

### Embodiment 5

As shown in FIG. 6, implantation regions 62 and 63 with the same junction depth are sequentially disposed on a front side and a back side of a substrate 61 respectively. The implantation region 63 on the back side is connected to the substrate 61 through metal 66, so that the implantation region 63 on the back side of the substrate 61 is short-circuited with the substrate 61. The implantation region 62 on the front side of the substrate 61 is connected to metal 65. A conductivity type of the implantation region 62 on the front side of the substrate 61 is the same as that of the implantation region 63 on the back side of the substrate 61, but is different from that of the substrate 61. A trough 67 is formed on the substrate 61. The trough 67 covers the first implantation region 62, and a separation layer 64 is implanted on a wall of the trough 67. The separation layer 64 is made of silicon dioxide. The separation layer 64 separates the metal 65 from the substrate 61 to prevent short circuit (that is, currents flow from the metal 61 on the front side to the substrate 61 and then to the metal 66 on the back side). In addition, the separation layer 64 can isolate the side edge of a pn junction formed between the first implantation region 62 on the front side of the substrate and the substrate 61 from the external environment, preventing the pn junction from being affected by the external environment. The substrate 61 may be P-type, and the implantation region 62 and the implantation region 63 are both N-type. Depth of a pn junction between the implantation region 62 on the front side of the substrate 61 and the substrate 61 is the same as depth of a pn junction between the implantation region 63 on the back side and the substrate 61. Protection against a negative surge is implemented only by a forward-biased pn junction between the substrate 61 and the implantation region 62 on the front side of the substrate 61. In this case, the surge protection capability is weak. To solve the problem in the prior art, the embodiment of this application provides a technical solution.

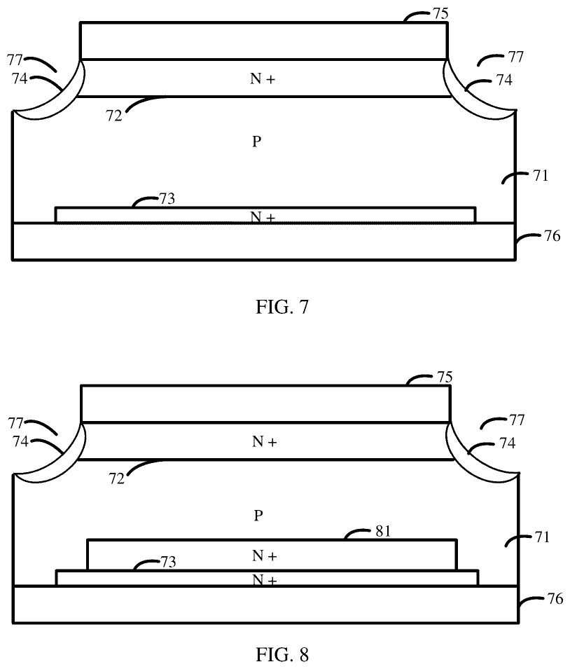

As shown in FIG. 7, Embodiment 5 differs from Embodiment 1 in that a substrate 71 is provided with a trough 77. The trough 77 covers a first implantation region 72, an insulation layer 74 is implanted on a wall of the trough 77, and depth of the trough 77 is greater than depth of a pn junction formed between the first implantation region 72 and the substrate 71. The first implantation region 72 is disposed on a front side of the substrate 71, a second implantation region 73 is disposed on a back side of the substrate 71, and depth of a pn junction formed between the second implantation region 73 and the substrate 21 is less than the depth of the pn junction formed between the first implantation region 72 and the substrate 71. First metal is led out of the first implantation region 72 as a first electrode, and second metal is led out of the second implantation region 73 on the back side and the substrate 71 respectively as a second electrode, so that the second implantation region 73 on the back side of the substrate is short-circuited with the substrate 71. The first conductivity type is different from the second conductivity type.

In the embodiment of this application, width of the second implantation region 73 is greater than that of the first implantation region 72, mainly in consideration of allocation of positive and negative surge protection capabilities. A wider second implantation region 73 on the back side corresponds to a higher positive surge protection capability but a lower negative surge protection capability. The second implantation region 73 on the back side being wider than the first implantation region 72 on the front side allows the positive and negative surge protection capabilities to be effectively allocated.

### Embodiment 6

On a basis of Embodiment 5, as shown in FIG. 8, the diode in the embodiment of this application further includes a third implantation region 81 of the second conductivity type. The width of the second implantation region 73 is greater than the width of the third implantation region 81, and depth of a pn junction formed between the third implantation region 81 and the substrate 71 is greater than the depth of the pn junction formed between the first implantation region 72 and the substrate 71. The second implantation region 73 is heavily doped. In the embodiment of this application, if the substrate 71 is P-type, the third implantation region 81 is N-type; and if the substrate 71 is N-type, the third implantation region 81 is P-type. In the embodiment of this application, the first conductivity type is P-type, and the second conductivity type is N-type. In another embodiment, the first conductivity type may be N-type and the second conductivity type is P-type. In the embodiment of this application, the third implantation region 81 shortens a base region that includes the first implantation region 72 on the front side, the substrate 71, and the second implantation region 73 on the back side, increasing the current magnification factor and thereby increasing the current-carrying capability.

In the embodiment of this application, width of the second implantation region 73 is greater than that of the first implantation region 72, mainly in consideration of allocation of positive and negative surge protection capabilities. A wider second implantation region 73 on the back side corresponds to a higher positive surge protection capability but a lower negative surge protection capability The second implantation region 73 on the back side being wider than the first implantation region 72 on the front side allows the positive and negative surge protection capabilities to be effectively allocated.

### Embodiment 7

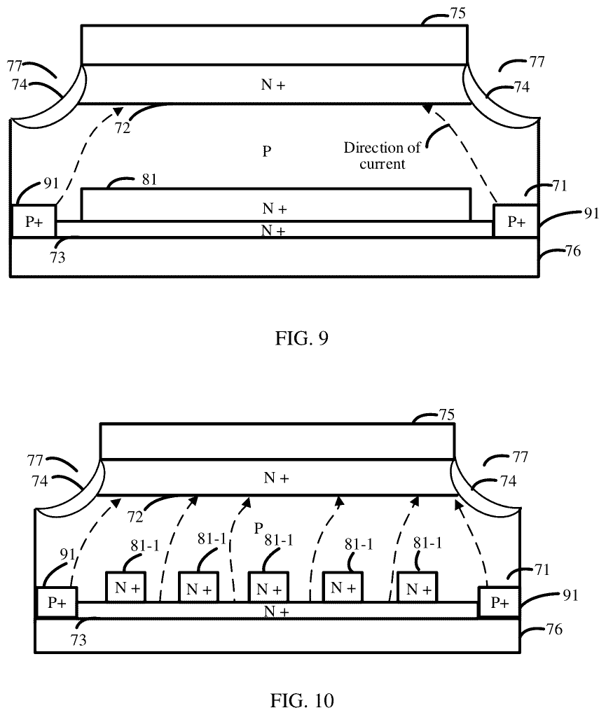

On a basis of Embodiment 6, as shown in FIG. 9, the diode in the embodiment further includes a fourth implantation region 91 of the second conductivity type. The fourth implantation region 91 covers the second implantation region 73 and is in contact with the second implantation region 73. In the fourth implantation region 91, a pn junction greatly vulnerable to Zener breakdown is formed. This pn junction is between the fourth implantation 91 and the second implantation region 73 on the back side, allowing currents to flow through more easily.

### Embodiment 8

On a basis of Embodiment 7, as shown in FIG. 10, the third implantation region 81 includes a plurality of segmented implantation regions 81-1 that are evenly spaced apart.

It should be noted that the third implantation region 81 in Embodiment 6 may also include a plurality of segmented implantation regions spaced apart.

In the embodiment of this application, when a negative surge occurs, the path from the second implantation region 73 on the back side of the substrate to the first implantation region 72 on the front side of the substrate 71 can be conducted more easily, allowing current to flow on rather than gather at both ends as shown in FIG. 9.

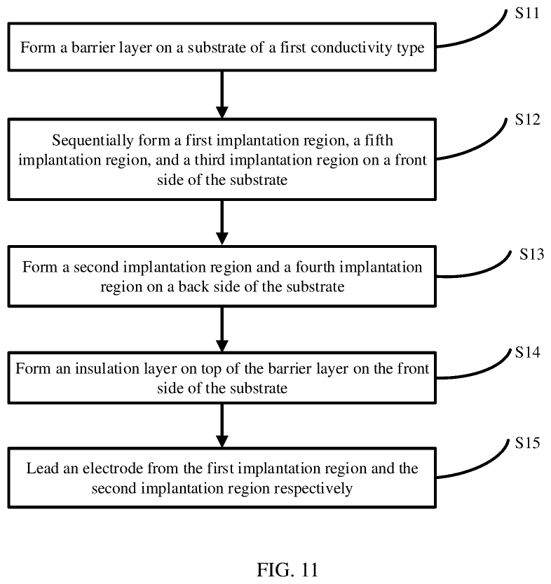

As shown in FIG. 11, an embodiment of this application further provides a manufacturing process of unidirectional transient voltage suppression diode. The manufacturing process is used for manufacturing the unidirectional transient voltage suppression diode according to embodiments 1 to 4.

The process includes the following steps.

Step S11. Form a barrier layer on a substrate of a first conductivity type.

Step S12. Sequentially form a first implantation region on a front side of the substrate and a second implantation region on a back side, where the first implantation region and the second implantation region are of the first conductivity type, depth of a pn junction formed between the second implantation region and the substrate is less than depth of a pn junction formed between the first implantation region and the substrate, and the first conductivity type is different from a second conductivity type.

Step S13. Form an insulation layer on top of the barrier layer on the front side of the substrate.

Step S14. Lead first metal out of the first implantation region as a first electrode, where the insulation layer is disposed between the barrier layer and a first metal layer, and lead second metal out of the second implantation region and the substrate respectively as a second electrode, so that the second implantation region on the back side of the substrate is short-circuited with the substrate.

It should be noted that the first-time oxidation is performed on the substrate to form a barrier layer. Photolithography is performed on the front side to define a pattern of the first implantation region, followed by impurity implantation or pre-diffusion and high-temperature diffusion, so as to form the first implantation region on the front side of the substrate. Then photolithography is performed on the back side of the substrate to define the second implantation region, followed by impurity implantation or pre-diffusion and then activation by short-term high temperature, so as to form the second implantation region on the back side of the substrate. Subsequently, an insulation layer is implanted on the front side of the substrate. Finally, contact holes of appropriate sizes are photo-etched on the front and back sides of the substrate, followed by metal deposition and etching, so as to form the final device. The diode with a structure described in Embodiment 1 can be obtained by performing steps S11 to S14.

Before the forming a second implantation region in step S12, the process further includes the following step.

Step S16. Form a third implantation region of the second conductivity type on the back side of the substrate, where width of the second implantation region is greater than width of the third implantation region, and depth of a pn junction formed between the third implantation region and the substrate is greater than the depth of the pn junction formed between the first implantation region and the substrate.

It should be noted that photolithographing and ion implantation can be performed concurrently on the first implantation region and second implantation region on the front and back sides of the substrate. In other words, photolithography is performed simultaneously on the front side and back side of the substrate to define the first implantation region and third implantation region respectively, followed by impurity implantation or pre-diffusion and high-temperature diffusion, so as to form the first implantation region and the third implantation region. Photolithography is performed on the back side of the substrate to define the second implantation region, followed by impurity implantation or pre-diffusion and then activation by short-term high temperature, so as to form the second implantation region on the back side. The diode with a structure according to Embodiment 2 can be obtained by performing steps S11 to S15.

Alternatively, this step may be performed in such a way that the first implantation region on the front side of the substrate is first made, then the third implantation region, and finally the second implantation region. FIG. 11 merely illustrates one process for forming the third implantation region, in which the first implantation region and the third implantation region are formed simultaneously.

If the third implantation region is made into a plurality of segmented implantation regions spaced apart through photolithographing, the diode with a structure according to Embodiment 4 can be obtained by performing steps S11 to S15.

At the time of forming a second implantation region in step S12, the process further includes the following step:
forming a fourth implantation region of the first conductivity type on the back side of the substrate, wherein the fourth implantation region covers the second implantation region and is in contact with the second implantation region.

FIG. 11 merely illustrates one process for forming the third implantation region, in which the second implantation region and the fourth implantation region are formed simultaneously.

It should be noted that while the second implantation region is being photolithographed, photolithography is performed on the back side of the substrate to define the fourth implantation region, followed by impurity implantation or pre-diffusion and high-temperature diffusion, so as to form the fourth implantation region on the back side of the substrate. In the embodiment of this application, the fourth implantation region may alternatively be formed prior to the second implantation region.

Before the forming a second implantation region in step S12, the process further includes the following step:
forming a fifth implantation region of the first conductivity type on the front side of the substrate, where the fifth implantation region covers the first implantation region and is spaced apart from the first implantation region by a predetermined distance. The diode with a structure according to Embodiment 3 can be obtained by performing steps S11 to S14 and S16.

It should be noted that while the first implantation region is being formed, photolithography is performed on the front side of the substrate to define the fifth implantation region, followed by impurity implantation or pre-diffusion and high-temperature diffusion, so as to form the fifth implantation region on the front side of the substrate. This manner can reduce process steps and costs. The fifth implantation region may alternatively be formed prior to the second implantation region. In doing so, depth of implantation regions on the back side will not be affected by the high-temperature diffusion for the fifth implantation region. FIG. 11 merely illustrates one process for forming the third implantation region, in which the first implantation region and the fifth implantation region are formed simultaneously.

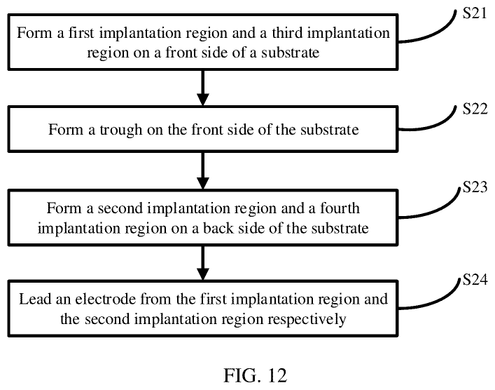

As shown in FIG. 12, an embodiment of this application further provides a manufacturing process of unidirectional transient voltage suppression diode. The manufacturing process includes the following steps.

Step S21. Form a first implantation region on a front side of a substrate.

Step S22. Form a trough on the substrate and implant a separation layer in the trough, where the trough covers the first implantation region, and depth of the trough is greater than depth of a pn junction formed between the first implantation region and the substrate.

Step S23. Form a second implantation region on a back side of the substrate, where the first implantation region and the second implantation region are of a first conductivity type, depth of a pn junction formed between the second implantation region and the substrate is less than the depth of the pn junction formed between the first implantation region and the substrate, and the first conductivity type is different from a second conductivity type.

Step S24. Lead first metal out of the first implantation region as a first electrode and lead second metal out of the second implantation region and the substrate respectively as a second electrode, so that the second implantation region on the back side of the substrate is short-circuited with the substrate.

It should be noted that photolithography is performed on the front side to define a pattern of the first implantation region, followed by impurity implantation or pre-diffusion and high-temperature diffusion, so as to form the first implantation region on the front side of the substrate. Then the trough is formed by dry etching or wet etching. Subsequently, photolithography is performed on the back side of the substrate to define the second implantation region, followed by impurity implantation or pre-diffusion and then activation by short-term high temperature, so as to form the second implantation region on the back side of the substrate. Finally, contact holes of appropriate sizes are photo-etched on the front and back sides of the substrate, followed by metal deposition and etching, so as to form the final device. The diode with a structure according to Embodiment 5 can be obtained by performing steps S21 to S24.

Before the forming a second implantation region in step S23, the process further includes the following step.

Step S25. Form a third implantation region of the second conductivity type on the back side of the substrate, where width of the second implantation region is greater than width of the third implantation region, and depth of a pn junction formed between the third implantation region and the substrate is greater than the depth of the pn junction formed between the first implantation region and the substrate.

It should be noted that photolithographing and ion implantation can be performed concurrently on the first implantation region and second implantation region on the front and back sides of the substrate. In other words, photolithography is simultaneously performed on the front side and back side of the substrate to define the first implantation region and the third implantation region respectively, followed by impurity implantation or pre-diffusion and high-temperature diffusion, so as to form the first implantation region on the front side of the substrate and the third implantation region on the back side of the substrate. Then photolithography is performed on the back side of the substrate to define the second implantation region, followed by impurity implantation or pre-diffusion and then activation by short-term high temperature, so as to form the second implantation region on the back side. The diode with a structure according to Embodiment 6 can be obtained by performing steps S21 to S25.

Alternatively, this step may be performed in such a way that the first implantation region on the front side of the substrate is first made, then the third implantation region, and finally the second implantation region. FIG. 12 merely illustrates one process for forming the third implantation region, in which the first implantation region and the third implantation region are formed simultaneously.

If the third implantation region is made into a plurality of segmented implantation regions evenly spaced apart through photolithographing, the diode with a structure according to Embodiment 8 can be obtained by performing steps S21 to S25.

At the time of forming a second implantation region in step S23, the process further includes the following step:
forming a fourth implantation region of the first conductivity type on the back side of the substrate, wherein the fourth implantation region covers the second implantation region and is in contact with the second implantation region.

FIG. 12 merely illustrates one process for forming the third implantation region, in which the second implantation region and the fourth implantation region are formed simultaneously.

It should be noted that while the second implantation region is being photolithographed, photolithography is performed on the back side of the substrate to define the fourth implantation region, followed by impurity implantation or pre-diffusion and high-temperature diffusion, so as to form the fourth implantation region on the back side of the substrate. In the embodiment of this application, the fourth implantation region may alternatively be formed prior to the second implantation region.

It should be noted that the fourth implantation region may alternatively be formed prior to the second implantation region. Photolithography is performed on the back side of the substrate to define the fourth implantation region, followed by impurity implantation or pre-diffusion and high-temperature diffusion, so as to form the fourth implantation region on the back side of the substrate. The diode with a structure according to Embodiment 7 can be obtained by performing steps S21 to S24 and S26.

The various technical features mentioned in the foregoing embodiments may be combined in any manners. For ease of description, some possible combinations of the various technical features in the foregoing embodiments are not described herein. However, all combinations of these technical features shall be considered to fall within the scope of the specification in absence of conflicts.

Although the present invention is described with reference to the embodiments, the foregoing descriptions and accompanying drawings are merely exemplary rather than limiting. The present invention is not limited to the embodiments disclosed herein. Without departing from the spirit of the present invention, various modifications and variations are possible.

1-18. (canceled)

19. A unidirectional transient voltage suppression diode, comprising: a substrate of a first conductivity type, and a first implantation region and a second implantation region of a second conductivity type; wherein
the first implantation region is disposed on a front side of the substrate, the second implantation region is disposed on a back side of the substrate, and depth of a pn junction formed between the second implantation region and the substrate is less than depth of a pn junction formed between the first implantation region and the substrate; and
a barrier layer and an insulation layer are arranged in sequence on a front surface of the substrate from the bottom up; first metal is led out of the first implantation region as a first electrode, the insulation layer is disposed between the barrier layer and a first metal layer, and second metal is led out of the second implantation region on the back side and the substrate respectively as a second electrode, so that the second implantation region on the back side of the substrate is short-circuited with the substrate; and the first conductivity type is different from the second conductivity type.

20. The unidirectional transient voltage suppression diode according to claim 19, wherein the diode further comprises a third implantation region of the second conductivity type; wherein
a width of the second implantation region is greater than a width of the third implantation region, and depth of a pn junction formed between the third implantation region and the substrate is greater than the depth of the pn junction formed between the first implantation region and the substrate.

21. The unidirectional transient voltage suppression diode according to claim 20, wherein the third implantation region comprises a plurality of segmented implantation regions spaced apart.

22. The unidirectional transient voltage suppression diode according to claim 19, wherein the diode further comprises a fourth implantation region of the first conductivity type and/or a fifth implantation region of the second conductivity type; wherein
the fourth implantation region covers the second implantation region and is in contact with the second implantation region; and the fifth implantation region covers the first implantation region and is spaced apart from the first implantation region by a predetermined distance.

23. The unidirectional transient voltage suppression diode according to claim 19, wherein the first conductivity type is P-type, and the second conductivity type is N-type.

24. The unidirectional transient voltage suppression diode according to claim 19, wherein the barrier layer is made of silicon dioxide, and the insulation layer is phosphorus-doped silica.

25. A unidirectional transient voltage suppression diode, comprising: a substrate of a first conductivity type, a first implantation region and a second implantation region of a second conductivity type, and a trough; wherein
the first implantation region is disposed on a front side of the substrate, the second implantation region is disposed on a back side of the substrate, and depth of a pn junction formed between the second implantation region and the substrate is less than depth of a pn junction formed between the first implantation region and the substrate; and
the trough covers the first implantation region, a separation layer is implanted on a wall of the trough, depth of the trough is greater than the depth of the pn junction formed between the first implantation region and the substrate, first metal is led out of the first implantation region as a first electrode, second metal is led out of the second implantation region on the back side and the substrate respectively as a second electrode so that the second implantation region on the back side of the substrate is short-circuited with the substrate, and the first conductivity type is different from the second conductivity type.

26. The unidirectional transient voltage suppression diode according to claim 25, wherein the diode further comprises a third implantation region of the second conductivity type; wherein
a width of the second implantation region is greater than a width of the third implantation region, and depth of a pn junction formed between the third implantation region and the substrate is greater than the depth of the pn junction formed between the first implantation region and the substrate.

27. The unidirectional transient voltage suppression diode according to claim 26, wherein the third implantation region comprises a plurality of segmented implantation regions spaced apart.

28. The unidirectional transient voltage suppression diode according to claim 26, wherein the diode further comprises a fourth implantation region of the first conductivity type;
wherein the fourth implantation region covers the second implantation region and is in contact with the second implantation region.

29. The unidirectional transient voltage suppression diode according to claim 28, wherein the first conductivity type is P-type, and the second conductivity type is N-type.

30. A manufacturing process of unidirectional transient voltage suppression diode, wherein the manufacturing process is used for manufacturing the diode according to claim 19, the manufacturing process comprising:
forming a barrier layer on a substrate of a first conductivity type;
sequentially forming a first implantation region on a front side of the substrate and a second implantation region on a back side, wherein the first implantation region and the second implantation region are of the first conductivity type, depth of a pn junction formed between the second implantation region and the substrate is less than depth of a pn junction formed between the first implantation region and the substrate, and the first conductivity type is different from a second conductivity type;
forming an insulation layer on top of the barrier layer on the front side of the substrate; and
leading first metal out of the first implantation region as a first electrode, wherein the insulation layer is disposed between the barrier layer and a first metal layer, and leading second metal out of the second implantation region and the substrate respectively as a second electrode, so that the second implantation region on the back side of the substrate is short-circuited with the substrate.

31. The manufacturing process of unidirectional transient voltage suppression diode according to claim 30, wherein before the forming a second implantation region on a back side of the substrate, the manufacturing process further comprises:
forming a third implantation region of the second conductivity type on the back side of the substrate, wherein width of the second implantation region is greater than width of the third implantation region, and depth of a pn junction formed between the third implantation region and the substrate is greater than the depth of the pn junction formed between the first implantation region and the substrate.

32. The manufacturing process of unidirectional transient voltage suppression diode according to claim 30, wherein before the forming a second implantation region on a back side of the substrate, the manufacturing process further comprises:
forming a fourth implantation region of the first conductivity type on the back side of the substrate, wherein the fourth implantation region covers the second implantation region and is in contact with the second implantation region.

33. The manufacturing process of unidirectional transient voltage suppression diode according to claim 30, wherein before the forming a second implantation region on a back side of the substrate, the manufacturing process further comprises:
forming a fifth implantation region of the first conductivity type on the front side of the substrate, wherein the fifth implantation region covers the first implantation region and is spaced apart from the first implantation region by a predetermined distance.
